(19) United States
(12) Patent Application Publication
(10) Pub. No.: US 2016/0351869 A1
(43) Pub. Date: Dec. 1, 2016

(54) POWER SOURCE DEVICE

(71) Applicant: YAZAKI CORPORATION, Tokyo (JP)

(72) Inventors: Yoshiaki Ichikawa, Shizuoka (JP); Koji Koizumi, Shizuoka (JP); Hirotaka Mukasa, Shizuoka (JP)

(21) Appl. No.: 15/234,206

(22) Filed: Aug. 11, 2016

Related U.S. Application Data
(63) Continuation of application No. PCT/JP2015/054849, filed on Feb. 20, 2015.

(30) Foreign Application Priority Data
Feb. 20, 2014 (JP) 2014-030716

(51) Int. Cl. H01M 2/10; H01M 2/20; G01R 31/36; H01M 10/48

(52) U.S. Cl. CPC H01M 2/1077; H01M 10/482; H01M 2/206; G01R 31/362; G01R 31/3658; G01R 31/3696; H01M 2220/20

(57) ABSTRACT

A power source device includes: a battery assembly comprising a plurality of batteries which are arranged such that electrodes having different polarities of the batteries are adjacent to each other; a plurality of bus bars which are attached to two electrode rows of the battery assembly, and which connect positive electrodes and negative electrodes which are adjacent to each other in each of the electrode rows; a plurality of holding members, each of which holds, for each of a plurality of battery groups formed by dividing the battery assembly into the battery groups, the bus bars attached to the electrode rows of the batteries belonging to the corresponding one of the battery groups; and a plurality of battery monitoring units, each of which monitors, for each of the battery groups, voltages of batteries belonging to the corresponding one of the battery groups.

### CROSS REFERENCE TO RELATED APPLICATION(S)

This application is a continuation of PCT application No. PCT/JP2015/054849, which was filed on Feb. 20, 2015, based on Japanese Patent Application (No. 2014-030716) filed on Feb. 20, 2014, the contents of which are incorporated herein by reference.

### BACKGROUND OF THE INVENTION

1. Field of the Invention

The present invention relates to a power source device.

2. Description of the Related Art

A power source device is installed in, for example, electric vehicles which run using an electric motor and hybrid vehicles which run using both of an engine and an electric motor (refer to JP-A-2013-105571).

The power source device disclosed in JP-A-2013-105571 is equipped with a battery assembly including plural batteries (rechargeable batteries), a bus bar module which is attached to electrode rows formed in the battery assembly, voltage detection lines whose negative ends are connected to voltage detection terminals for detection of voltages of the batteries, respectively, and a battery monitoring unit to which the other ends of the voltage detection lines are connected and which serves to detect voltages of the respective batteries. In the battery assembly, the batteries are integrated being bundled together by confining bands or the like in a state that they are held between a pair of end plates. The positive electrode and the negative electrode of each battery project from its top so as to be spaced from each other, and the batteries are arranged in such a manner that they are opposite in orientation alternately and the positive electrode of one battery is adjacent to the negative electrode of the adjacent battery. The bus bar module is formed by connecting plural bus bar housing portions each of which houses plural bus bars each of which connects adjoining batteries in series by connecting the positive electrode of one of them to the negative electrode of the other.

### SUMMARY OF THE INVENTION

Incidentally, power source devices are demanded to be increased in output power to enhance the performance of electric vehicles and hybrid vehicles, and one measure is to increase the number of batteries constituting a battery assembly. For example, in the power source device disclosed in JP-A-2013-105571, a DC current is output from a battery assembly in which one stack includes a little more than 10 batteries. On the other hand, in this power source device, one bus bar module (or one set of bus bar modules) is attached to one stack of batteries, whereby adjoining batteries are connected to each other in series by connecting their adjoining positive electrode and negative electrode in each electrode row to each other. Furthermore, in this power source device, a voltage across a little more than 10 batteries of one stack is detected by one battery monitoring unit. Therefore, as the number of batteries constituting one stack increases, a higher voltage comes to develop across the one stack of batteries connected to each other by one bus bar module and to be applied to the one battery monitoring unit.

Where a battery assembly includes a large number of batteries (e.g., one stack includes a little more than 10 batteries or several tens of batteries), it is particularly important to secure safety in doing prescribed work (e.g., replacement work or maintenance work) on the bus bar module or the battery monitoring unit. And it is necessary to secure safety in a similar manner in, for example, a case of connecting several stacks of batteries by one bus bar module or monitoring their voltage by one battery monitoring unit.

The present invention has been made in view of the above circumstances, and an object thereof is to provide a power source device that allows, for example, work of replacing a busbar module or a battery monitoring unit safely even in a case that a battery assembly includes a large number of batteries.

The above-described problem can be solved by the configurations described below.

(1) A power source device including: a battery assembly including a plurality of batteries which are arranged such that electrodes having different polarities of the batteries are adjacent to each other; a plurality of bus bars which are attached to two electrode rows of the battery assembly, and which connect positive electrodes and negative electrodes which are adjacent to each other in each of the electrode rows; a plurality of holding members, each of which holds, for each of a plurality of battery groups formed by dividing the battery assembly into the battery groups, the bus bars attached to the electrode rows of the batteries belonging to the corresponding one of the battery groups; and a plurality of battery monitoring units, each of which monitors, for each of the battery groups, voltages of batteries belonging to the corresponding one of the battery groups.

According to the power source device having the configuration of item (1), it is possible to divide the battery assembly into the plurality of battery groups such that a total voltage of the batteries belonging to each of the battery groups is set lower than or equal to a safety voltage (e.g., 50 to 70 V, preferably about 60 V). Therefore, each of the holding members can be attached separately to the corresponding battery group whose total voltage is lower than or equal to the safety voltage. Further, since a maximum voltage detected by each of the battery monitoring units is the total voltage of the batteries belonging to the monitoring target battery group, the maximum voltage detected can be made lower than or equal to the safety voltage.

(2) The power source device according to item (1), wherein each of the holding members includes bus bar housing portions which are connected to each other and which are arranged in two rows extend in parallel to each other a longitudinal direction of the battery assembly so as to correspond to the two electrode rows, respectively, and wherein each of the battery monitoring units and the bus bar housing portions arranged in two rows extending in the longitudinal direction of the battery assembly are arranged along a short direction of the battery assembly between the bus bar housing portions.

According to the power source device having the configuration of item (2), the individual holding member corresponding to a trouble-ridden battery monitoring unit can be removed easily, which increases the efficiency of replacement work further.

According to the present invention, it is possible to provide a power source device that allows, for example, work of replacing a busbar module or a battery monitoring unit safely even in a case that a battery assembly includes a large number of batteries.

### BRIEF DESCRIPTION OF THE DRAWINGS

FIG. 1 is a perspective view showing the overall configuration of a power source device according to an embodiment of the present invention.

FIG. 2 is a plan view showing the overall configuration of the power source device according to the embodiment of the invention.

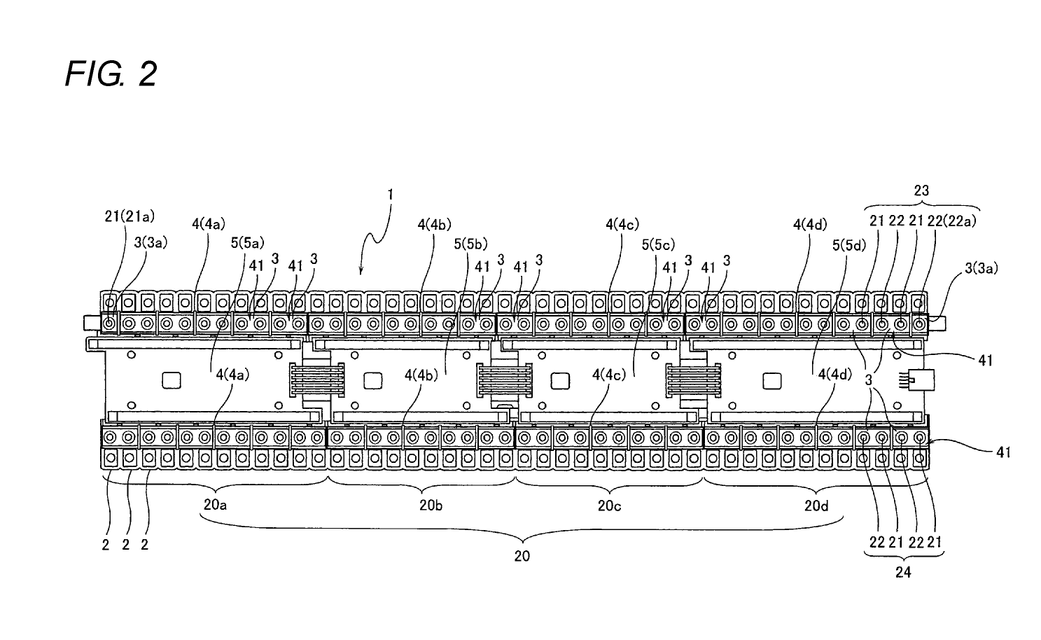

### DETAILED DESCRIPTION OF THE EXEMPLARY EMBODIMENTS

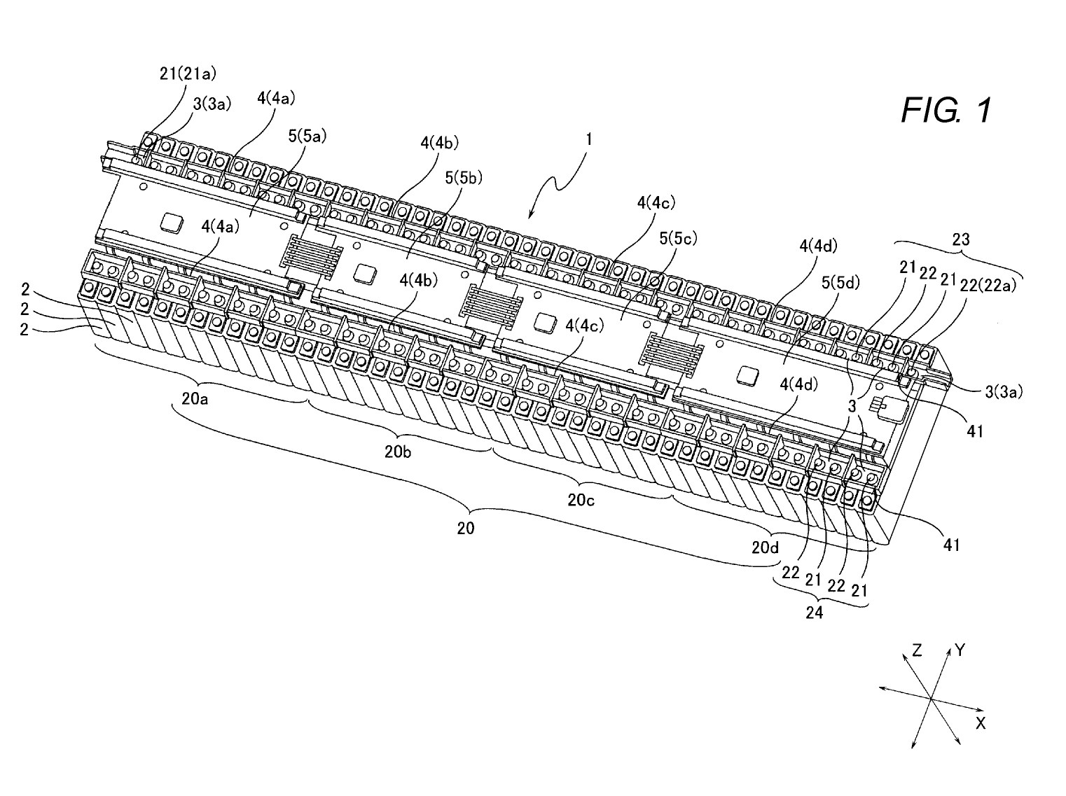

A power source device according to an embodiment of the present invention will be hereinafter described with reference to the accompanying drawings.

Whereas the power source device according to the embodiment of the invention can be used as, for example, a power supply device for an electric motor that is installed in an electric vehicle, a hybrid vehicle, or the like, the uses of the power source device are not limited to it. In the following description, the directions indicated by arrows X, Y, and Z in FIG. 1 will be referred to as the front-rear direction, the left-right direction, and the top-bottom direction, respectively. As for the top-bottom direction, the upward direction (or top side) is defined as the direction (or the side) indicated by the upward direction in FIG. 1, and the downward direction (or bottom side) is defined as the direction (or the side) indicated by the downward direction in FIG. 1. However, these front-rear direction, left-right direction, and top-bottom direction need not always coincide with the directions to be used in a state that the power source device is installed in a vehicle (e.g., the front-rear direction, left-right direction, and top-bottom direction of the vehicle).

As shown in FIG. 1, the power source device 1 according to the embodiment includes: a battery assembly 20 including a plurality of batteries 2 which are arranged such that electrodes 21 and 22 having different polarities of the batteries 2 are adjacent to each other; a plurality of bus bars 3 which are attached to two electrode rows 23 and 24 of the battery assembly 20, and which connect the positive electrodes 21 and the negative electrodes 22 which are adjacent to each other in each of the electrode rows 23 and 24; a plurality of holding members 4, each of which holds, for each of a plurality of battery groups formed by dividing the battery assembly 20 into the battery groups 20a-20d, the bus bars 3 attached to the electrode rows 23 and 24 of the batteries 2 belonging to the corresponding one of the battery group, and a plurality of battery monitoring units 5, each of which monitors, for each of the battery groups, voltages of the batteries 2 belonging to the corresponding one of the battery groups. That is, the power source device 1 according to the embodiment is equipped with the plurality of holding members 4 and the plurality of battery monitoring units 5 which are the same in number as the battery groups formed by dividing the battery assembly 20 (the plurality of batteries 2).

In the above configuration, each battery group includes plural batteries 2 the sum of whose voltages is set lower than or equal to a safety voltage (e.g., 50 to 70 V, preferably about 60 V). That is, the battery assembly 20 is divided into battery groups that produce voltages that are lower than or equal to the safety voltage. In the example configuration shown in FIG. 1, the battery assembly 20 is divided into four battery groups 20a-20d. There are no particular limitations on the number of batteries belonging to each battery group as long as the sum of the voltages across these batteries is set lower than or equal to the safety voltage. Every battery group may include the same number of batteries and, alternatively, the battery groups may include different numbers of batteries. It is possible to set the number of batteries constituting each battery group to any number as long as the voltage of the battery group is lower than or equal to the safety voltage. In this connection, the division of the battery assembly 20 into the battery groups, that is, the sets of batteries the sum of whose voltages is lower than or equal to the safety voltage is just for the purpose of convenience. It is not indispensable to divide the battery assembly itself physically or structurally. That is, it suffices that the units (holding members 4; described later) of holding of batteries 2 that are connected to each other by bus bars 3 and the units (battery monitoring units 5) of monitoring of voltages of target batteries 2 be separated from each other physically or structurally.

Each of the batteries 2 constituting the battery assembly 20 is approximately shaped like a rectangular parallelepiped, and a cylindrical positive electrode 21 projects from the top of the battery 2 at one end and a cylindrical negative electrode 22 projects from the top of the battery 2 at the other end so as to be threadedly engageable with respective nuts. The batteries 2 are arranged so that they are opposite in orientation alternately and the positive electrode 21 of one battery is adjacent to the negative electrode 22 of the adjacent battery, and the battery assembly 20 is formed by bundling the batteries 2 together. To insulate adjoining batteries from each other, a member (spacer) may be interposed between them. Each battery 2 may be housed in and held by an insulative holding case.

Each bus bar 3 is formed by, for example, subjecting a conductive flat plate to punching, bending, etc. and has holes (electrode holes) through which to insert the positive electrode 21 and the negative electrode 22 of adjoining batteries 2. Each bus bar 3 is fixed to the battery assembly 20 by threadedly engaging respective nuts or the like to the positive electrode 21 and the negative electrode 22 that project and are inserted in the respective electrode holes, and the positive electrode 21 and the negative electrode 22 of the adjoining batteries 2 are connected together and the adjoining batteries 2 are connected to each other in series. Incidentally, each bus bar 3 that connects the positive electrode 21 and the negative electrode 22 of adjoining batteries 2 to connect the adjoining batteries 2 in series is formed with two electrode holes. On the other hand, each bus bar 3a that is connected to a terminal positive electrode 21a or a terminal negative electrode 22a of the battery assembly 20 is formed with only one electrode hole. The terminal positive electrode 21a is the positive electrode 21 of the battery 2 that is located at one end in the front-rear direction, and the terminal negative electrode 22a is the negative electrode 22 of the battery 2 that is located at the other end in the front-rear direction. The power source device 1 is configured so that a DC output of the battery assembly 20 is obtained between the terminal positive electrode 21a and the terminal negative electrode 22a.

A voltage detection line for detection of voltages across the batteries 2 connected by each bus bar 3 is connected to the bus bar 3. For example, a voltage detection line is connected electrically to each bus bar 3 via a voltage detection terminal that is formed separately from the bus bar 3 by subjecting a conductive flat plate to punching, bending, etc. or a wire joining portion that is formed in the bus bar 3 for the purpose of joining of a voltage detection line. Where the voltage detection terminal is used, the conductor of the voltage detection line may be joined to a crimp portion that is formed in the voltage detection terminal. The voltage detection terminal is formed with a through-hole through which to insert one electrode (positive electrode 21 or negative electrode 22) to which the bus bar 3 is connected and a nut or the like is threadedly engaged with the electrode 21 or 22 that projects and is inserted in the through-hole, whereby the voltage detection terminal is fixed to the battery assembly 20 together with the bus bar 3. Where the wire joining portion is used, a portion, exposed by peeling off part of an insulation covering, of the conductor of the voltage detection line may be joined to the wire joining portion by ultrasonic joining, soldering, or the like.

The holding member 4 is made of an insulating material such as a resin, and is configured in such a manner that two rows of bus bar housing portions 41 connected to each other extend in the front-rear direction (longitudinal direction of the battery assembly 20) so as to correspond to the respective electrode rows 23 and 24 of the battery assembly 20. Deformation of the holding member 4 (more specifically, distortion of the bus bar housing portions 41) etc. at the occurrence of thermal expansion or contraction can be prevented by connecting each adjoining pair of bus bar housing portions 41 with a hinge (i.e., elastic bent piece). Each bus bar housing portion 41 is configured so as to house one bus bar 3 in a housing room that is surrounded by a frame-shaped circumferential wall erected from the bottom of the holding member 4. The bus bar 3 is configured so as to be able to be held by the bus bar housing portion 41 when housed therein by locking a nail or the like projecting from the circumferential wall on it. Instead of locking using the nail, the bus bar 3 may be held by, for example, joining with adhesive. The holding member 4 may be formed with, in the arrangement direction (front-rear direction) of the batteries 2, wire routing portions for routing of the voltage detection lines. This makes it possible to wire the voltage detection lines that are connected to the batteries 2 via the bus bars 3, smoothly adjacent to the holding member 4. In this manner, the bus bars 3 are housed in and held by the bus bar housing portions 41, and the holding member 4 having the wire routing portions by which the voltage detection lines connected to the bus bars 3 are wired is attached, as a bus bar module, to the electrode rows 23 and 24 of the battery assembly 20.

In the embodiment, the holding member 4 holds, for each of the four divisional battery groups 20a-20d of the battery assembly 20, the bus bars 3 that are attached to the electrode rows of the batteries 2 belonging to the battery group 20a, 20b, 20c, or 20d. Therefore, the holding member 4 is configured so as to be separable into a first holding member 4a, a second holding member 4b, a third holding member 4c, and a fourth holding member 4d. Although in the embodiment the holding member 4 is configured so as to be separable into the four members, the point is that the holding member is separable into plural members of the same number as the number of batter groups constituting the battery assembly.

The battery monitoring unit 5 is an electronic component for detecting voltages of the respective batteries 2 and controlling charging/discharging etc. of the individual batteries 2 on the basis of the detected voltage values, and is equipped with a circuit board having a microcomputer and circuits for detecting voltages of the respective batteries 2, currents, a temperature, etc., which are housed in a case and disposed between the electrode rows 23 and 24 of the battery assembly 20. It is desirable that the battery monitoring unit 5 be attached to, for example, a top portion of a smoke exhaust duct that is provided to exhaust gas generated from inside an abnormal battery 2, and that the battery monitoring unit 5 and the two rows of bus bar housing portions 41 extending in the longitudinal direction of the battery assembly 20 are arranged in the short direction (left-right direction) of the battery assembly 20 in approximately the same plane in such a manner that the battery monitoring unit 5 is located between the two rows of bus bar housing portions 41. A unit holding portion for holding the battery monitoring unit 5 may be formed between the two rows of bus bar housing portions 41 of the holding member 4 integrally with them. The battery monitoring unit 5 is connected to the bus bars 3 via the respective voltage detection lines and thereby connected electrically to the batteries 2. Thus, voltages of the respective batteries 2 are output to the battery monitoring unit 5 via the voltage detection lines. There are no particular limitations on the method for electrical connection between the battery monitoring unit 5 and the voltage detection lines. For example, the battery monitoring unit 5 is formed with connectors for connection to the voltage detection lines and electrical connection is established between the battery monitoring unit 5 and the voltage detection lines by connecting, to these connectors, connectors provided for the respective voltage detection lines. This makes it possible to connect the voltage detection lines to the battery monitoring unit 5 easily and to remove the voltage detection lines from the battery monitoring unit 5 easily.

In the embodiment, the battery monitoring unit 5 monitors, for each of the four divisional battery groups 20a-20d of the battery assembly 20, voltages of the batteries 2 belonging to the battery group 20a, 20b, 20c, or 20d. Therefore, the power source device 1 is equipped with a first battery monitoring unit 5a, a second battery monitoring unit 5b, a third battery monitoring unit 5c, and a fourth battery monitoring unit 5d. Although in the embodiment the four battery monitoring units 5a-5d are provided, the point is that plural battery monitoring units are provided in the same number as the battery groups constituting the battery assembly.

As described above, according to the embodiment, since the total voltages of the four respective battery groups 20a-20d are set lower than or equal to the safety voltage (e.g., 50 to 70V; preferably about 60 V), the four holding members 4a-4d can be attached separately to the four respective battery groups 20a-20d whose total voltages are lower than or equal to the safety voltage. Furthermore, since a maximum voltage detected by each of the four battery monitoring units 5a-5d is the sum of voltages across the batteries 2 belonging to the monitoring target battery group 20a, 20b, 20c, or 20d, the maximum voltage detected can be made lower than or equal to the safety voltage.

Therefore, even when prescribed work is performed on the first to fourth holding members 4a-4d or the first to fourth battery monitoring units 5a-5d, it can be done under the safety voltage. That is, even where a battery assembly includes a large number of batteries, by employing the configuration that as in the embodiment the battery assembly is divided into plural battery groups whose total voltages are set lower than or equal to the safety voltage and holding units (specifically, bus bar modules) and battery monitoring units are provided for the respective battery groups, safety of work performed on these holding members or battery monitoring units can be secured. For example, even in the case of a battery assembly in which one stack including a little more than 10 or several tens of batteries 2, safety of the work can be secured reliably by performing replacement work on an individual bus bar module or battery monitoring unit when trouble has occurred in the bus bar modules or the battery monitoring units. Furthermore, the efficiency of work can be increased because it suffices to replace only an individual bus bar module or battery monitoring unit where trouble has occurred, that is, it is not necessary to replace the entire bus bar module or battery monitoring unit.

Each of the first to fourth battery monitoring units 5a-5d and the associated two rows of bus bar housing portions 41 of the first holding portion 4a, the second holding portion 4b, the third holding portion 4c, or the fourth holding portion 4d are arranged in the short direction of the battery assembly 20 in approximately the same plane in such a manner that the first battery monitoring unit 5a, second battery monitoring unit 5b, third battery monitoring unit 5c, or fourth battery monitoring unit 5d is located between the two rows of bus bar housing portions 41. As a result, the first holding portion 4a, second holding portion 4b, third holding portion 4c, or fourth holding portion 4d corresponding to a trouble-ridden one of the first to fourth battery monitoring units 5a-5d can easily be removed individually, which increases the efficiency of replacement work further.

Where unit holding portions for holding the respective first to fourth battery monitoring units 5a-5d are formed integrally with the respective first to fourth holding members 4a-4d, one of the first to fourth holding members 4a-4d can be removed together with the corresponding one of the first to fourth battery monitoring units 5a-5d, which facilitates the replacement work.

Although the embodiment has been described above, the above-described embodiment is just an example of the invention and the invention is not limited to only the configuration of the above-described embodiment. It is apparent to those skilled in the art that modifications or changes are possible without departing from the spirit and scope of the invention. And such changes or modifications should naturally be construed as being included in the claims of this application.

Now, the features of the above-described power source device according to the embodiment of the invention will be summarized below concisely in an itemized manner:

[1] A power source device (1) including:

a battery assembly (20) including a plurality of batteries (2) which are arranged such that electrodes (positive electrode 21, negative electrode 22) having different polarities of the batteries (2) are adjacent to each other;

a plurality of bus bars (3) which are attached to two electrode rows (23, 24) of the battery assembly (20), and which connect positive electrodes (21) and negative electrodes (22) which are adjacent to each other in each of the electrode rows (23, 24);

a plurality of holding members (first holding member 4a, second holding portion 4b, third holding portion 4c, fourth holding portion 4d), each of which holds, for each of a plurality of battery groups (20a-20d) formed by dividing the battery assembly (20) into the battery groups (20a-20d), the bus bars (3) attached to the electrode rows (23, 24) of the batteries (2) belonging to the corresponding one of the battery groups (20a, 20b, 20c, or 20d); and

a plurality of battery monitoring units (first battery monitoring unit 5a, second battery monitoring unit 5b, third battery monitoring unit 5c, fourth battery monitoring unit 5d), each of which monitors, for each of the battery groups (20a-20d), voltages of batteries (2) belonging to the corresponding one of the battery groups (20a, 20b, 20c, or 20d).

[2] The power source device (1) according to item [1],

wherein each of the holding members (4a-4d) includes bus bar housing portions (41) which are connected to each other and which are arranged in two rows extending in parallel to each other in a longitudinal direction of the battery assembly (20) so as to correspond to the two electrode rows (23, 24), respectively, and

wherein each of the battery monitoring units (5a-5d) and the bus bar housing portions (41, 41) arranged in two rows extending in the longitudinal direction of the battery assembly (20) are arranged along a short direction of the battery assembly (20) between the bus bar housing portions (41, 41).

The power source device according to the invention allows, for example, work of replacing a busbar module or a battery monitoring unit safely, even in a case that a battery assembly includes a large number of batteries, the power source device being for installation in, for example, electric vehicles which run using an electric motor and hybrid vehicles which run using both of an engine and an electric motor.

1. A power source device comprising:
a battery assembly comprising a plurality of batteries which are arranged such that electrodes having different polarities of the batteries are adjacent to each other;
a plurality of bus bars which are attached to two electrode rows of the battery assembly, and which connect positive electrodes and negative electrodes which are adjacent to each other in each of the electrode rows;
a plurality of holding members, each of which holds, for each of a plurality of battery groups formed by dividing the battery assembly into the battery groups such that a total voltage of the batteries belonging to each of the battery groups is set lower than or equal to a safety voltage in a range from 50 to 70 V, the bus bars attached to the electrode rows of the batteries belonging to the corresponding one of the battery groups; and
a plurality of battery monitoring units, each of which monitors, for each of the battery groups, voltages of batteries belonging to the corresponding one of the battery groups.

2. The power source device according to claim 1,
wherein each of the holding members comprises bus bar housing portions which are connected to each other and which are arranged in two rows extending in parallel to each other in a longitudinal direction of the battery assembly so as to correspond to the two electrode rows, respectively, and
wherein each of the battery monitoring units and the bus bar housing portions arranged in two rows extending in the longitudinal direction of the battery assembly are arranged along a short direction of the battery assembly between the bus bar housing portions.
